(19) United States
(12) Patent Application Publication
(10) Pub. No.: US 2021/0083691 A1
(43) Pub. Date: Mar. 18, 2021

(54) TURBO ENCODING METHOD, TURBO ENCODER AND UAV

(71) Applicant: SZ DJI TECHNOLOGY CO., LTD., Shenzhen (CN)

(72) Inventors: Ying LIU, Shenzhen (CN); Chunhua ZHAI, Shenzhen (CN)

(21) Appl. No.: 17/096,140

(22) Filed: Nov. 12, 2020

Related U.S. Application Data
(63) Continuation of application No. PCT/CN2018/086799, filed on May 15, 2018.

(51) Int. Cl. H03M 13/27; H03M 13/29; H03M 13/00; G06F 12/0884; G06F 12/0817

(52) U.S. Cl. CPC H03M 13/2771; H03M 13/2903; G06F 12/082; G06F 12/0884; H03M 13/6508

(57) ABSTRACT

A turbo encoding method includes obtaining a code block for turbo encoding, storing a data block of the code block in a plurality of parallel caches, and obtaining parallel data from the plurality of parallel caches for turbo encoding.

### CROSS-REFERENCE TO RELATED APPLICATION

This application is a continuation of International Application No. PCT/CN2018/086799, filed on May 15, 2018, the entire content of which is incorporated herein by reference.

### TECHNICAL FIELD

The present disclosure relates to the technical field of communication and, more particularly, to a turbo encoding method, a turbo encoder, and an unmanned aerial vehicle (UAV).

### BACKGROUND

A channel encoding is generally performed on data before an uplink or downlink transmission of the data. The common channel encoding methods include turbo encoding. During turbo encoding, the upstream or downstream data is serially input to a turbo encoder. The turbo encoder includes two encoders. A first encoder directly encodes the serially input data. A second encoder is connected to an interleaver, and the serially input data is processed by the interleaver and then transmitted to the second encoder for encoding. An encoding rate of the conventional turbo encoding is low.

### SUMMARY

In accordance with the disclosure, there is provided a turbo encoding method including obtaining a code block for turbo encoding, storing a data block of the code block in a plurality of parallel caches, and obtaining parallel data from the plurality of parallel caches for turbo encoding.

Also in accordance with the disclosure, there is provided a turbo encoder including a communication interface configured to obtain a code block for turbo encoding, a plurality of parallel caches connected to the communication interface, one or more processors operating individually or cooperatively, connected to the communication interface, and configured to control the communication interface to store a data block of the code block in the plurality of parallel caches, a first branch encoder connected to the plurality of parallel caches and configured to obtain parallel data from the plurality of parallel caches for turbo encoding, an interleaver connected to the plurality of parallel caches, and a second branch encoder connected to the interleaver and configured to obtain the parallel data from the plurality of parallel caches for turbo encoding via the interleaver.

Also in accordance with the disclosure, there is provided an unmanned aerial vehicle including a body, a wireless communication device arranged at the body and configured to perform wireless communication, a power system arranged at the body and configured to provide power, and a turbo encoder. The turbo encoder includes a communication interface configured to obtain a code block for turbo encoding, a plurality of parallel caches connected to the communication interface, one or more processors operating individually or cooperatively, connected to the communication interface, and configured to control the communication interface to store a data block of the code block in the plurality of parallel caches, a first branch encoder connected to the plurality of parallel caches and configured to obtain parallel data from the plurality of parallel caches for turbo encoding, an interleaver connected to the plurality of parallel caches, and a second branch encoder connected to the interleaver and configured to obtain the parallel data from the plurality of parallel caches for turbo encoding via the interleaver.

### BRIEF DESCRIPTION OF THE DRAWINGS

In order to provide a clearer illustration of technical solutions of disclosed embodiments, the drawings used in the description of the disclosed embodiments are briefly described below. It will be appreciated that the disclosed drawings are merely examples and other drawings conceived by those having ordinary skills in the art on the basis of the described drawings without inventive efforts should fall within the scope of the present disclosure.

FIG. 1 is a schematic structural diagram of a conventional turbo encoder.

FIG. 2 schematically shows a communication scenario consistent with embodiments of the disclosure.

FIG. 3 is a schematic flow chart of a turbo encoding method consistent with embodiments of the disclosure.

FIG. 4 is a schematic diagram of a data storage with 8 caches consistent with embodiments of the disclosure.

FIG. 5 is a schematic flow chart of another turbo encoding method consistent with embodiments of the disclosure.

FIG. 6 is a schematic flow chart of another turbo encoding method consistent with embodiments of the disclosure.

FIG. 7 is a schematic structural diagram of a turbo encoder consistent with embodiments of the disclosure.

### DETAILED DESCRIPTION OF THE EMBODIMENTS

In order to provide a clearer illustration of technical solutions of disclosed embodiments, example embodiments will be described with reference to the accompanying drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

As used herein, when a first component is referred to as “fixed to” a second component, it is intended that the first component may be directly attached to the second component or may be indirectly attached to the second component via another component. When a first component is referred to as “connecting” to a second component, it is intended that the first component may be directly connected to the second component or may be indirectly connected to the second component via a third component between them.

Unless otherwise defined, all the technical and scientific terms used herein have the same or similar meanings as generally understood by one of ordinary skill in the art. As described herein, the terms used in the specification of the present disclosure are intended to describe example embodiments, instead of limiting the present disclosure. The term “and/or” used herein includes any suitable combination of one or more related items listed.

Example embodiments will be described with reference to the accompanying drawings. Unless conflicting, the exemplary embodiments and features in the exemplary embodiments can be combined with each other.

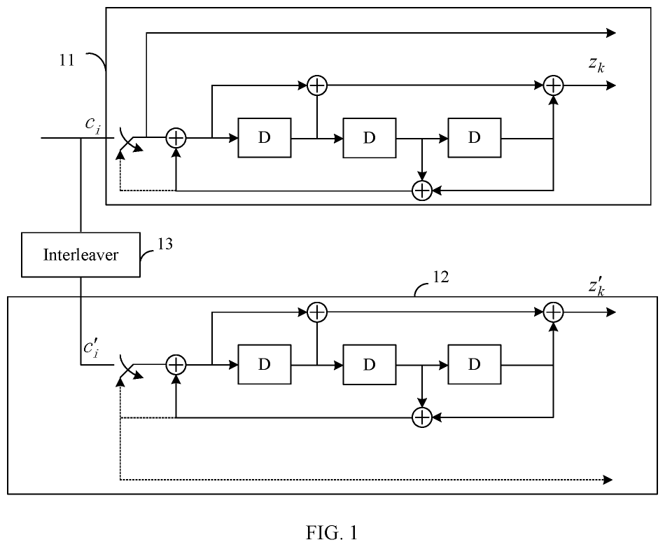

FIG. 1 is a schematic structural diagram of an example turbo encoder. As shown in FIG. 1, the turbo encoder includes two 8-state branch encoders, i.e., a first branch encoder 11 and a second branch encoder 12, and an interleaver 13. The second branch encoder 12 is connected to the interleaver 13 of the turbo encoder. In a communication scenario, when data of a transmission block to be sent is large, code block division processing may be performed on the transmission block to obtain a plurality of code blocks of length K+ and K−, where K+ and K− are positive integers. For the simplification of description, assumes that the plurality of code blocks obtained by dividing the transmission block is c₀, c₁, c₂, c₃, . . . , c_{K-1}, where cᵢ is the i-th code block from c₀ to c_{K-1}. The plurality of code blocks c₀, c₁, c₂, c₃, . . . , c_{K-1} can be serially input to the turbo encoder. In the turbo encoder, the first branch encoder 11 can directly encode the serially input code blocks, and output first encoded data z_{K}. The interleaver 13 can perform interleaving processing on the serially input code blocks, and the second branch encoder 12 can encode output data of the interleaver 13, and output second encoded data z′ₖ. A relationship between the input and output of the interleaver 13 can be as follows:

c′ᵢ=c_{Π(i)} i=0,1, . . . ,(K−1)

A relationship between an output sequence number i and an input sequence number Π(i) can satisfy the following quadratic form:

Π(i)=(f₁·i+f₂·i²)mod K

where parameters f₁ and f₂ depend on the length of the code block K, and the parameters f₁ and f₂ can be obtained through a preset correspondence list of K, f₁ and f₂.

In the turbo encoder shown in FIG. 1, the data to be encoded is serial data, and thus, an encoding efficiency of the turbo encoder can be low. Moreover, when the interleaver performs the interleaving processing, a lot of intermediate variables can be generated. The intermediate variables can occupy a large cache size. As such, a complex application-specific integrated circuit (ASIC) can be required to support the turbo encoder, thereby increasing a cost of the turbo encoder.

In order to solve the problems described above, the present disclosure provides a turbo encoding method. The method can obtain the code block for turbo encoding, store data blocks of the code block in a plurality of parallel caches, and obtain parallel data from the plurality of parallel caches for turbo encoding. Therefore, a parallel storage and reading of the data can be realized during turbo encoding, thereby improving the efficiency of turbo encoding. Compared with the conventional serial mode, the method consistent with the present disclosure can reduce the number of intermediate variables generated during the interleaving processing of turbo encoding, and thus, can reduce the cost of the ASIC in the turbo encoder.

Hereinafter, example embodiments will be described with reference to the accompanying drawings.

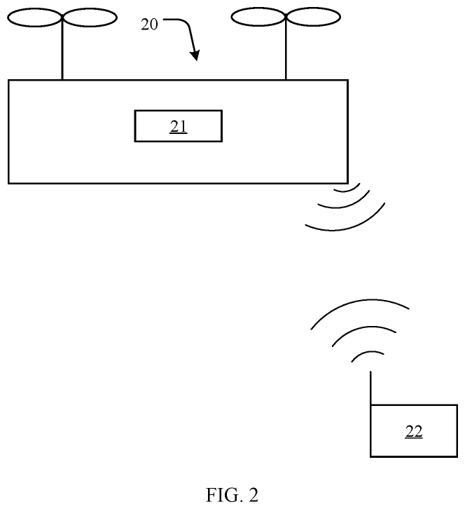

The present disclosure provides an example turbo encoding method, which can be executed by a turbo encoder arranged at a device having a wireless communication function, e.g., an aircraft. FIG. 2 schematically shows an example communication scenario consistent with the disclosure. As shown in FIG. 2, an aircraft 20, a turbo encoder 21 arranged at the aircraft 20, and a ground station 22 are included in the communication scenario. The ground station 22 can include a device having a wireless communication function, a computing function and/or a processing function. The device can include, for example, a remote controller, a smart phone, a tablet computer, a laptop computer, a watch, a bracelet, or the like, and a combination thereof. The aircraft 20 can include an unmanned aircraft, a helicopter, a manned fixed-wing aircraft, a hot air balloon, or any suitable aircraft having the wireless communication function. As shown in FIG. 2, the ground station 22 and the aircraft 20 are connected through a mobile communication network (for example, but not limited to, a 4G or 5G mobile communication network). When the aircraft 20 communicates with the ground station 22, the transmission data can be encoded using the turbo encoding method consistent with the disclosure.

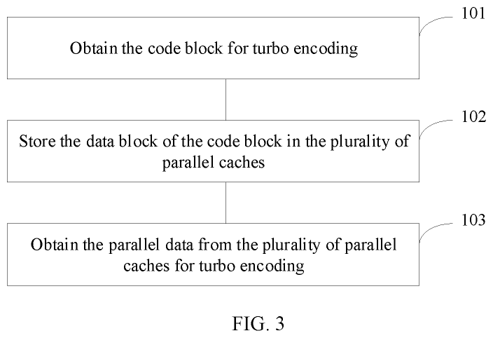

FIG. 3 is a schematic flow chart of an example turbo encoding method consistent with the disclosure. As shown in FIG. 3, at 101, the code block for turbo encoding is obtained.

At 102, the data block of the code block is stored in the plurality of parallel caches.

At 103, the parallel data is obtained from the plurality of parallel caches for turbo encoding.

Herein, the code block for turbo encoding can refer to a code block obtained by performing the code block division processing on the transmission block to be transmitted. That is, “code block division processing” refers to division processing on a transmission block to obtain code blocks.

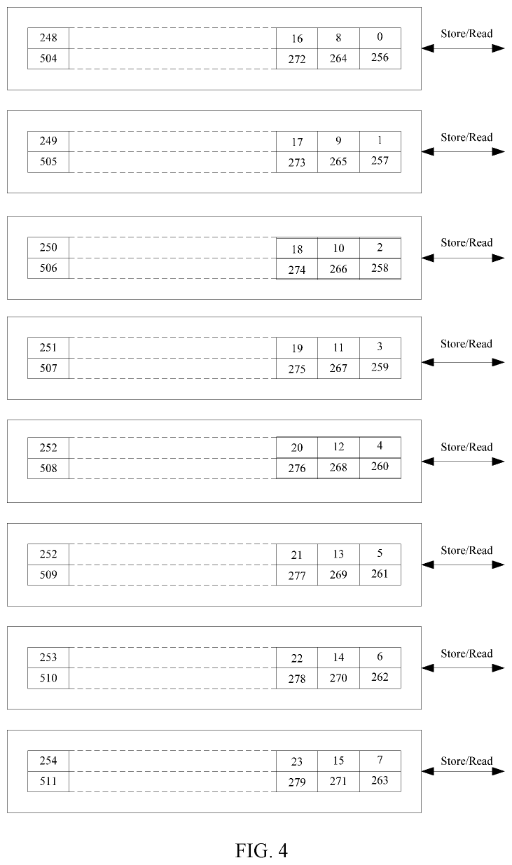

In some embodiments, the number of the parallel caches can be set according to actual needs. Herein, take 8 parallel caches as an example. FIG. 4 is a schematic diagram of an example data storage with 8 caches consistent with the disclosure. As shown in FIG. 4, the 8 caches are connected in parallel. The 8 caches can include dual-port type caches or single-port type caches. For example, all of the 8 caches can be dual-port type caches.

When the code block to be encoded is input to the turbo encoder, the turbo encoder can store the data block of the code block in the 8 parallel caches according to a preset storage strategy. In a first branch, the first branch encoder can read the data from the 8 caches, sort the read data according to the preset storage strategy, and encode a data stream obtained after sorting (also referred to as a “sorted data stream”). In a second branch, the interleaver can resort the sorted data stream obtained in the first branch based on a preset interleaving relationship, and the second branch encoder can encode a data stream generated after resorting (also referred to as a “resorted data stream”). The storage strategy for data in the parallel caches can be set according to actual needs. In some embodiments, a first example storage strategy can include storing a first data bit in the code block in a first cache, storing a second data bit in a second cache, storing a third data bit in the code block in a third cache, storing a fourth data bit in the code block in a fourth cache, storing a fifth data bit in the code block in a fifth cache, storing a sixth data bit in the code block in a sixth cache, storing a seventh data bit in the code block in a seventh cache, and storing an eighth data bit in an eighth cache. The storage process described above can be executed cyclically from a ninth data bit. In some embodiments, a second example storage strategy can include performing block division processing on the code block, such that each data block obtained after the block division processing can include 8 data bits, and then the data of each data block can be stored as described in the first example storage strategy. “Block division processing” can refer to division processing on a code block to obtain data blocks. In some embodiments, on the basis of the first example storage strategy, a preset amount of data (e.g., 2-bit data, 3-bit data, or the like) can be stored in one cache each time. Correspondingly, in the data reading and sorting process, a reverse process can be performed to read and sort the data. The example storage strategies described above are merely examples, and not intended to limit the present disclosure.

Consistent with the disclosure, the code block for turbo encoding can be obtained, the data block of the code block can be stored in the plurality of parallel caches, and the parallel data can be obtained from the plurality of parallel caches for turbo encoding. Therefore, the parallel storage and reading of the data can be realized during turbo encoding, thereby improving the efficiency of turbo encoding. Compared with the conventional serial mode, the method consistent with the present disclosure can reduce the number of intermediate variables generated during the interleaving process of turbo encoding, and thus, can reduce the cost of the ASIC in the turbo encoder.

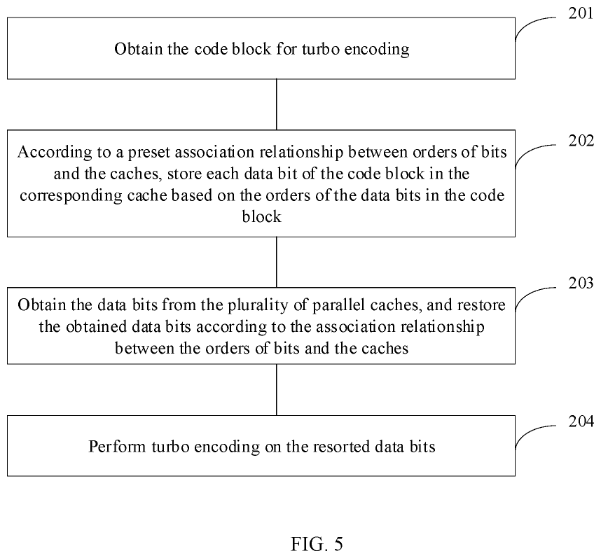

FIG. 5 is a schematic flow chart of another example turbo encoding method consistent with the disclosure. As shown in FIG. 5, at 201, the code block for turbo encoding is obtained.

At 202, according to a preset association relationship between orders of bits and the caches, each data bit of the code block is stored in the corresponding cache based on the order of the data bit in the code block.

At 203, the data bits from the plurality of parallel caches are obtained, and the obtained data bits are resorted according to the association relationship between the orders of bits and the caches.

At 204, turbo coding is performed on the resorted data bits.

Herein, the association relationship between the orders of bits and the caches can include positions of the data bits in the code block stored by each cache of the plurality of parallel caches. For simplification purposes, take the 8 parallel caches as an example for illustration. In some embodiments, a first example storage manner can include storing the data bits at positions of 0, 8, . . . , j×8, . . . in the code block into the first cache, storing the data bits at positions of 1, 9, . . . , j×8+1, . . . in the code block into the second cache, storing the data bits at positions of 2, 10, . . . , j×8+2, . . . in the code block into the third cache, storing the data bits at positions of 3, 11, . . . , j×8+3, . . . in the code block into the fourth cache, storing the data bits at positions of 4, 12, . . . , j×8+4, . . . in the code block into the fifth cache, storing the data bits at positions of 5, 13, . . . , j×8+5, . . . in the code block into the sixth cache, storing the data bits at positions of 6, 14, . . . , j×8+6, . . . in the code block into the seventh cache, and storing the data bits at positions of 7, 15, . . . , j×8+7, . . . in the code block into the eighth cache. In the description above, j represents an integer equaling or larger than 0. In some embodiments, the association relationship between the orders of bits and the caches can be set irregularly, for example, the preset orders of data bits stored in each cache can be irregular and can be specified. For example, the first cache can be set to store the data bits at positions 0, 3, 11, and the like, in the code block, and the second cache can be set to store the data bits at positions 1, 4, 16, or the like, in the code block. The example manners described above are merely for illustration and not intended to limit the present disclosure.

In some embodiments, the data can be read from the plurality of parallel caches and the read data can be resorted according to the association relationship between the orders of bits and the caches. Take the first example storage manner described above as an example of the association relationship between the orders of bits and the caches. In an operation of reading data, one data bit can be read from each cache in parallel, and the read data bits can be sorted in an order from the first cache to the eighth cache, and then the second, third, . . . , and nth reading can be performed. The data read each time can be sorted from the first cache to the eighth cache, and data strings read at the first reading, second reading, . . . , and nth reading can be stringed together to form the data stream. The first example manner is merely an example for illustration, and not intended to limit the present disclosure. When the association relationship between the orders of bits and caches is in other forms, a manner opposite to the data storage can be used to read data. According to the storage manner of the data, i.e., the association relationship between the orders of bits and the caches, the read data can be resorted.

In some embodiments, during turbo encoding, the first branch encoder can directly encode the data bits obtained after resorting the read data (also referred to as “first resorted data bits”). The interleaver on the second branch needs to resort the first resorted data bits based on the preset interleaving relationship to obtain second resorted data bits. The second branch encoder can then perform turbo encoding on the second resorted data bits. The interleaving relationship may include a relationship between the orders of the data bits before interleaving and after interleaving.

Hereinafter, the first example storage manner described above is taken as an example to illustrate an interleaving algorithm of the interleaver.

Assume that after resorting the first resorted data bits based on the association relationship between the orders of bits and caches, the order of the i-th data bit after being interleaved is f(i), then the preset interleaving relationship can be expressed as:

f(i)=(f1×i+f2×i×i)mod K

where K represents the length of the data, and

$$f ( i + N ) = ( f 1 \times ( i + N ) + f 2 \times ( i + N ) \times ( i + N ) ) mod K N = 0 to 7 , i = 0 , 8 , 16 , 24 , … = ( ( f 1 \times i + f 2 \times i \times i ) + ( f 1 \times N + 2 \times i \times N \times f 2 + f 2 \times N \times N ) ) mod K = ( ( f ( i ) mod K ) + ( ( f 1 \times N + 2 \times i \times N \times f 2 + f 2 \times N \times N ) mod K ) ) mod K$$

Set g(i,N)=(f1×N+2×i×N×f2+f2×N×N)mod K, and thus, f(i+N)=(f(i)+g(i,N))mod K.

Set const1(N)=(f1×N+f2×N×N)mod K and r(i,N)=(2×i×N×f2)mod K, and thus,

$$g ( i , N ) = ( const 1 ( N ) + r ( i , N ) ) mod K$$

$$\begin{matrix}f ( i + N ) = ( f ( i ) + g ( i , N ) ) mod K \\ = f ( i ) + ( ( const 1 ( N ) + r ( i , N ) ) mod K ) ) mod K\end{matrix}$$

Based on r(i,N)=(2×i×N×f2)mod K, it can be obtained that:

$$r ( 0 , N ) = 0 ;$$

$$r ( 8 , N ) = ( r ( 0 , N ) + 16 \times N \times f 2 ) mod K ;$$

$$r ( 16 , N ) = ( r ( 8 , N ) + 16 \times N \times f 2 ) mod K ;$$

$$⋮$$

$$\begin{matrix}r ( i + 8 , N ) = ( r ( i , N ) + ( 2 \times 8 \times N \times f 2 ) mod K ) ) mod K \\ = ( r ( i , N ) + c o n s t 2 ( N ) ) mod K\end{matrix}$$

If const1(N) and const2(N) can be calculated in advance (const1(N), const2(N) are less than K), calculating f(i+N)=(f(i)+const1(N)+r(i,N)) mod K each time can include two addition operations, a comparation of a calculation result obtained after two addition operations with K, 2×K, and then a subtraction of K or 2*K who is closer to the calculation result, as such an accurate result of f(i+N) can be obtained.

Take 8 parallel caches (e.g., N=0˜7) as an example, and based on the expression of r(i,N), the following calculation can be performed.

Initially set r(0,0)=0.

r(0,1) to r(0,8) can be calculated based on r(0,0), and r(8,0)=r(0,8).

r(8,1) to r(8,8) can be calculated based on r(8,0), and r(16,0)=r(8,8).

r(16,1) to r(16,8) can be calculated based on r(16,0), and r(24,0)=r(16,8), and so on.

The interleaving processing can obtain 8 interleaving addresses, denoted as N1 to N8, and the data bits read from the N1 to N8 interleaving addresses can include the input data of the second branch encoder.

The examples described above are merely for illustration and not intended to limit the present disclosure.

Consistent with the disclosure, after the code block for turbo encoding is obtained, based on the preset association relationship between the orders of bits and caches, each data bit in the obtained code block can be stored in the corresponding cache according to the order of the bit in the code block. During encoding, the data bits can be obtained from the plurality of parallel caches, and the obtained data bits can be resorted according to the association relationship between the orders of bits and caches. turbo encoding can be performed on the reordered data bits, such that a fast storage and reading of the data to be encoded can be realized conveniently and quickly, and the efficiency of turbo encoding can be improved.

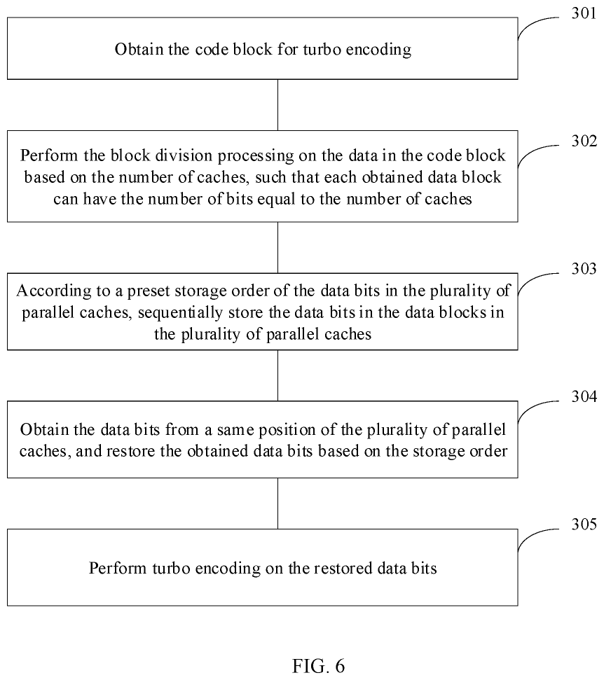

FIG. 6 is a schematic flow chart of another example turbo encoding method consistent with the disclosure. As shown in FIG. 6, at 301, the code block for turbo encoding is obtained.

At 302, the block division processing is performed on the data in the code block based on the number of caches, such that each obtained data block can have the number of bits equal to the number of caches.

At 303, according to a preset storage order of the data bits in the plurality of parallel caches, the data bits in the data blocks are sequentially stored in the plurality of parallel caches.

At 304, the data bits from a same position of the plurality of parallel caches are obtained, and the obtained data bits are resorted based on the storage order.

At 305, turbo encoding is performed on the restored data bits.

Take the 8 parallel caches as an example. When the block division processing is performed on the data in the code block, every 8 consecutive data bits can be put into a data block according to the orders of the data bits in the code block. The data bits in each data block can be stored in the 8 caches according to the preset storage order of the data bits in the 8 caches. For example, the first data bit can be stored in the first cache, the second data bit can be stored in the second cache, the third data bit can be stored in the third cache, the fourth data bit can be stored in the fourth cache, the fifth data bit can be stored in the fifth cache, the sixth data bit can be stored in the sixth cache, the seventh data bit can be stored in the seventh cache, and the eighth data bit can be stored in the eighth cache. The example described above is merely for illustration and not intended to limit the present disclosure.

In some embodiments, in order to facilitate the data reading, the data bits in each data block can be set to be sequentially stored in the same position in the caches. For example, each data bit in the first data block can be stored in a first bit of the corresponding cache, each data bit in the second data block can be stored in a second bit of the corresponding cache, and so on, until the data storage is completed.

Correspondingly, during data reading from the 8 parallel caches, the data bits can be read from the same position of the 8 caches each time. A first sorting order of each read data bit can be determined based on the storage order of the data bits, and the data bits can be sorted based on the first sorting order of each data bit to generate a first data stream. On the second branch, the interleaver can determine a second sorting order corresponding to the first sorting order of each data bit obtained from each cache based on the preset interleaving relationship. Each data bit can be sorted based on the second sorting order of each data bit to generate a second data stream. When turbo encoding is performed, the first branch encoder can encode the first data stream, and the second branch encoder can encode the second data stream.

Herein, the 8 parallel caches are merely examples for illustration, and not intended to limit the present disclosure.

The beneficial effects of the method in FIG. 6 are similar to those of the methods in FIGS. 3 and 5, and detailed description thereof is omitted herein.

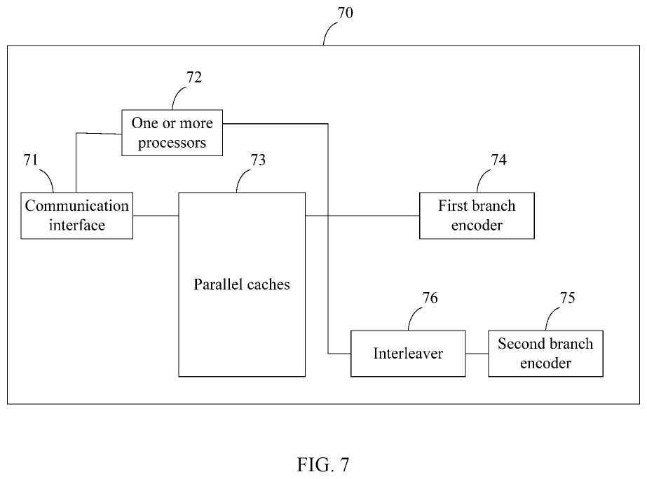

FIG. 7 is a schematic structural diagram of an example turbo encoder 70 consistent with the disclosure. As shown in FIG. 7, the turbo encoder 70 includes a communication interface 71, one or more processors 72, a plurality of parallel caches 73, a first branch encoder 74, a second branch encoder 75, and an interleaver 76. The one or more processors 72 can operate individually or cooperatively. The communication interface 71 is connected to the one or more processors 72. The communication interface 71 is connected to the plurality of parallel caches 73. The plurality of parallel caches 73 is connected to the first branch encoder 74 and the interleaver 76. The interleaver 76 is connected to the second branch encoder 75. The communication interface 71 can be configured to obtain the code block for turbo encoding. The one or more processors 72 can be configured to control the communication interface 71 to store the data block of the code block in the plurality of parallel caches 73. The first branch encoder 74 can be configured to obtain the parallel data from the plurality of parallel caches 73 for turbo encoding. The second branch encoder 75 can be configured to obtain the parallel data from the plurality of parallel caches 73 for turbo encoding via the interleaver 76.

In some embodiments, when controlling the communication interface 71 to store the data block of the code block in the plurality of parallel caches 73, the one or more processors 72 can store the data block of the code block in the plurality of parallel caches 73 according to the preset storage strategy.

In some embodiments, when storing the data block of the code block in the plurality of parallel caches 73 according to the preset storage strategy, the one or more processors 72 can, according to the preset association relationship between the orders of bits and the caches, store each data bit of the code block in the corresponding cache based on the orders of the data bits in the code block.

In some embodiments, when obtaining the parallel data from the plurality of parallel caches 73 for turbo encoding, the first branch encoder 74 can obtain the data bits from the plurality of parallel caches 73. The one or more processors 72 can be configured to, according to the association relationship between the orders of bits and the caches, resort the obtained data bits. The first branch encoder 74 can be configured to perform turbo coding on the resorted data bits. The resorted data bits can be also referred to as “first resorted data bits.”

In some embodiments, when the second branch encoder 75 obtains the parallel data from the plurality of parallel caches 73 for turbo encoding via the interleaver 76, the interleaver 76 can resort the first resorted data bits according to the preset interleaving relationship, and the second branch encoder 75 can perform turbo coding on the second resorted data bits.

In some embodiments, when storing the data block of the code block in the plurality of parallel caches 73 according to the preset storage strategy, the one or more processors 72 can to perform the block division processing on the data in the code block based on the number of caches 73, such that each obtained data block can have the number of bits equal to the number of caches 73, and according to the preset storage order of the data bits in the plurality of parallel caches 73, sequentially store the data bits in the data blocks in the plurality of parallel caches 73.

In some embodiments, when according to the preset storage order of the data bits in the plurality of parallel caches 73, sequentially storing the data bits in the data blocks in the plurality of parallel caches 73, the one or more processors 72 can sequentially store the data bits in each data block in the same position in the caches according to the preset storage order of the data bits in the plurality of parallel caches 73.

In some embodiments, when obtaining the parallel data from the plurality of parallel caches 73 for turbo encoding, the first branch encoder 74 can obtain the data bits from the same position of the plurality of parallel caches 73. The one or more processors 72 can be configured to restore the obtained data bits based on the storage order. The first branch encoder 74 can be further configured to perform turbo encoding on the restored data bits.

In some embodiments, when restoring the obtained data bits based on the storage order, the one or more processors 72 can determine the first sorting order of each read data bit based on the storage order of the data bits, and sort the data bits based on the first sorting order of each data bit to generate the first data stream. The first branch encoder 74 can be configured to perform turbo encoding on the first data stream.

In some embodiments, when the second branch encoder 75 obtains the parallel data from the plurality of parallel caches 73 for turbo encoding via the interleaver 76, the interleaver can determine the second sorting order corresponding to the first sorting order of each data bit obtained from each cache based on the preset interleaving relationship, and sort each data bit based on the second sorting order of each data bit to generate the second data stream. The second branch encoder 75 can be configured to perform turbo encoding on the second data stream.

The present disclosure further provides an unmanned aerial vehicle (UAV). The UAV can include a body, a wireless communication device arranged at the body and configured to perform the wireless communication, a power system arranged at the body and configured to provide power, and a turbo encoder consistent with the disclosure (e.g., the turbo encoder 70 in FIG. 7). The UAV can include an unmanned aircraft or an unmanned vehicle.

The present disclosure further provides a computer-readable storage medium. The computer-readable storage medium can store instructions, when being executed by a computer, causing the computer to execute the turbo encoding method consistent with the disclosure (e.g., the turbo encoding methods in FIGS. 3, 5, and 6). The computer can include a device with computing and processing capabilities, for example, but is not limited to, a UAV, a mobile phone, or the like. The computer-readable storage medium can include a storage medium storing executable instructions of the device.

The disclosed systems, apparatuses, and methods may be implemented in other manners not described here. For example, the devices described above are merely illustrative. For example, the division of units may only be a logical function division, and there may be other ways of dividing the units. For example, multiple units or components may be combined or may be integrated into another system, or some features may be ignored, or not executed. Further, the coupling or direct coupling or communication connection shown or discussed may include a direct connection or an indirect connection or communication connection through one or more interfaces, devices, or units, which may be electrical, mechanical, or in other form.

The units described as separate components may or may not be physically separate, and a component shown as a unit may or may not be a physical unit. That is, the units may be located in one place or may be distributed over a plurality of network elements. Some or all of the components may be selected according to the actual needs to achieve the object of the present disclosure.

In addition, the functional units in the various embodiments of the present disclosure may be integrated in one processing unit, or each unit may be an individual physically unit, or two or more units may be integrated in one unit. The integrated unit can be realized in the form of hardware, or in the form of hardware plus software functional unit.

A method consistent with the disclosure can be implemented in the form of computer program stored in a non-transitory computer-readable storage medium, which can be sold or used as a standalone product. The computer program can include instructions that enable a computer device, such as a personal computer, a server, or a network device, to perform part or all of a method consistent with the disclosure, such as one of the example methods described above. The storage medium can be any medium that can store program codes, for example, a USB disk, a mobile hard disk, a read-only memory (ROM), a random access memory (RAM), a magnetic disk, or an optical disk.

It will be apparent to those skilled in the art that the division of the above functional modules are considered as example only for the convenience and conciseness of the description. In practical applications, the above functions can be allocated to different functional modules according to the requirements. That is, the internal structure of the device can be divided into different functional modules to complete some or all of the functions described above. The working process of the device described above is similar to that of the method, and detailed description thereof is omitted herein.

It is intended that the specification and examples be considered as example only and not to limit the scope of the disclosure. Other embodiments of the disclosure will be apparent to those skilled in the art from consideration of the specification and practice of the embodiments disclosed herein. Other modifications of, or equivalents to the disclosed embodiments are intended to be encompassed within the scope of the present disclosure.

What is claimed is:

1. A turbo encoding method comprising:
obtaining a code block for turbo encoding;
storing a data block of the code block in a plurality of parallel caches; and
obtaining parallel data from the plurality of parallel caches for turbo encoding.

2. The method of claim 1, wherein storing the data block of the code block in the plurality of parallel caches includes:
storing the data block of the code block in the plurality of parallel caches according to a preset storage strategy.

3. The method of claim 2, wherein storing the data block of the code block in the plurality of parallel caches according to the preset storage strategy includes:
according to a preset association relationship between orders of data bits and the plurality of parallel caches, storing data bits of the code block in corresponding ones of the plurality of parallel caches based on the orders of the data bits in the code block.

4. The method of claim 3, wherein obtaining the parallel data from the plurality of parallel caches for turbo encoding includes:
obtaining the data bits from the plurality of parallel caches;
according to the association relationship between the orders of data bits and the plurality of parallel caches, resorting the obtained data bits; and
performing turbo coding on the resorted data bits.

5. The method of claim 4, wherein:
the resorted data bits are first restored data bits; and
performing turbo coding on the first resorted data bits includes:
resorting the first resorted data bits according to a preset interleaving relationship to obtain second resorted data bits; and
performing turbo coding on the second resorted data bits.

6. The method of claim 2, wherein storing the data block of the code block in the plurality of parallel caches according to the preset storage strategy includes:
performing block division processing on data in the code block based on a number of the plurality of parallel caches, such that a number of data bits in the data block equals the number of the plurality of parallel caches; and
according to a preset storage order, sequentially storing the data bits in the data block in the plurality of parallel caches.

7. The method of claim 6, wherein sequentially storing the data bits in the data block in the plurality of parallel caches includes:
sequentially storing each of the data bits in the data block in a same position in a corresponding one of the plurality of parallel caches according to the preset storage order.

8. The method of claim 7, wherein obtaining the parallel data from the plurality of parallel caches for turbo encoding includes:
obtaining the data bits each from the same position of the corresponding one of the plurality of parallel caches;
restoring the obtained data bits based on the storage order; and
performing turbo encoding on the restored data bits.

9. The method of claim 8, wherein:
obtaining the data bits each from the same position of the corresponding one of the plurality of parallel caches and restoring the obtained data bits based on the storage order include:
determining first sorting orders of the data bits obtained from the caches based on the storage order;
sorting the data bits based on the first sorting orders of the data bits to generate a first data stream;
determining second sorting orders corresponding to the first sorting orders of the data bits obtained from the caches based on a preset interleaving relationship; and
sorting the data bits based on the second sorting orders of the data bits to generate a second data stream; and
performing turbo encoding on the restored data bits includes:
performing turbo encoding on the first data stream and the second data stream.

10. A turbo encoder comprising:
a communication interface configured to obtain a code block for turbo encoding;
a plurality of parallel caches connected to the communication interface;
one or more processors operating individually or cooperatively, connected to the communication interface, and configured to control the communication interface to store a data block of the code block in the plurality of parallel caches;
a first branch encoder connected to the plurality of parallel caches and configured to obtain parallel data from the plurality of parallel caches for turbo encoding;
an interleaver connected to the plurality of parallel caches; and
a second branch encoder connected to the interleaver and configured to obtain the parallel data from the plurality of parallel caches for turbo encoding via the interleaver.

11. The encoder of claim 10, wherein the one or more processors are further configured to:
store the data block of the code block in the plurality of parallel caches according to a preset storage strategy.

12. The encoder of claim 11, wherein the one or more processors are further configured to:
according to a preset association relationship between orders of data bits and the plurality of parallel caches, store data bits of the code block in corresponding ones of the plurality of parallel caches based on the orders of the data bits in the code block.

13. The encoder of claim 12, wherein:
the first branch encoder is further configured to obtain the data bits from the plurality of parallel caches;
the one or more processors are further configured to, according to the association relationship between the orders of data bits and the plurality of parallel caches, resort the obtained data bits; and
the first branch encoder is further configured to perform turbo coding on the resorted data bits.

14. The encoder of claim 13, wherein:
the resorted data bits are first restored data bits;
the interleaver is further configured to resort the first resorted data bits according to a preset interleaving relationship to obtain second resorted data bits; and
the second branch encoder is further configured to perform turbo coding on the second resorted data bits.

15. The encoder of claim 11, wherein the one or more processors are further configured to:
perform block division processing on data in the code block based on a number of the plurality of parallel caches, such that a number of data bits in the data block equals the number of the plurality of parallel caches; and
according to a preset storage order, sequentially store the data bits in the data blocks in the plurality of parallel caches.

16. The encoder of claim 15, wherein the one or more processors are further configured to:
sequentially store each of the data bits in the data block in a same position in a corresponding one of the plurality of parallel caches according to the preset storage order.

17. The encoder of claim 16, wherein:
the first branch encoder is further configured to obtain the data bits each from the same position of the corresponding one of the plurality of parallel caches;
the one or more processors are further configured to restore the obtained data bits based on the storage order; and
the first branch encoder is further configured to perform turbo encoding on the restored data bits

18. The encoder of claim 17, wherein the one or more processors are further configured to:
determine first sorting orders of the data bits obtained from the caches based on the storage order; and
sort the data bits based on the first sorting orders of the datas bit to generate a first data stream.

19. The encoder of claim 18, wherein:
the interleaver is further configured to:
determine second sorting orders corresponding to the first sorting order of the data bits obtained from the caches based on a preset interleaving relationship; and
sort the data bits based on the second sorting orders of the data bits to generate a second data stream; and
the second branch encoder is further configured to perform turbo encoding on the second data stream.

20. An unmanned aerial vehicle (UAV) comprising:
a body;
a wireless communication device arranged at the body and configured to perform wireless communication;
a power system arranged at the body and configured to provide power; and
a turbo encoder including:
a communication interface configured to obtain a code block for turbo encoding;
a plurality of parallel caches connected to the communication interface;
one or more processors operating individually or cooperatively, connected to the communication interface, and configured to control the communication interface to store a data block of the code block in the plurality of parallel caches;
a first branch encoder connected to the plurality of parallel caches and configured to obtain parallel data from the plurality of parallel caches for turbo encoding;
an interleaver connected to the plurality of parallel caches; and
a second branch encoder connected to the interleaver and configured to obtain parallel data from the plurality of parallel caches for turbo encoding via the interleaver.
